(19) United States
(12) Patent Application Publication
(10) Pub. No.: US 2025/0259959 A1
(43) Pub. Date: Aug. 14, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventor: Woosang JUNG, Suwon-si (KR)

(73) Assignee: SAMSUNG ELECTRONICS CO., LTD., Suwon-si (KR)

(21) Appl. No.: 18/965,427

(22) Filed: Dec. 2, 2024

(30) Foreign Application Priority Data
Feb. 8, 2024 (KR) 10-2024-0019769

(51) Int. Cl. H01L 23/00; H01L 23/31; H01L 23/498; H01L 25/00; H01L 25/10

(52) U.S. Cl. CPC H01L 24/32; H01L 23/3107; H01L 23/49822; H01L 24/16; H01L 24/20; H01L 24/73; H01L 24/81; H01L 24/83; H01L 24/92; H01L 25/105; H01L 25/50; H01L 2224/16146; H01L 2224/211; H01L 2224/32145; H01L 2224/73204; H01L 2224/73209; H01L 2224/81193; H01L 2224/83022; H01L 2224/83192; H01L 2224/9211; H01L 2225/1041

(57) ABSTRACT

Semiconductor packages and their fabrication methods are provided. A semiconductor package includes a first redistribution layer, a first semiconductor chip on the first redistribution layer, a first adhesive layer on the first semiconductor chip, a first molding layer on the first redistribution layer, a second semiconductor chip on the first adhesive layer, a second adhesive layer on the second semiconductor chip, a second molding layer on the first molding layer, and a second redistribution layer on the second molding layer. The first semiconductor chip includes a first connection terminal that penetrates the first adhesive layer such as to be exposed at a top surface of the first adhesive layer. The second semiconductor chip includes a second connection terminal that penetrates the second molding layer such as to be coupled to the first connection terminal.

### CROSS-REFERENCE TO RELATED APPLICATION

This U.S. non-provisional application claims priority under 35 U.S.C § 119 to Korean Patent Application No. 10-2024-0019769, filed on Feb. 8, 2024, in the Korean Intellectual Property Office, the disclosure of which is hereby incorporated by reference in its entirety.

### BACKGROUND

### 1. Field

Embodiments of the present disclosure relate to a semiconductor package and a method of fabricating the same.

### 2. Brief Description of Related Art

With the development of the electronic industry, there have been increasing demands for electronic products to have high performance, high speed, and compact size. To meet the trend, there has recently been developed a packaging technology in which a plurality of semiconductor chips are mounted in a single package.

There has been an increasing demand for portable devices in recent electronic product markets, and as a result, it has been ceaselessly required for reduction in size and weight of electronic parts mounted on the portable devices. In order to accomplish the reduction in size and weight of the electronic parts, there is need for technology to integrate a number of individual devices into a single package as well as technology to reduce individual sizes of mounting parts. A large number of adhesive members are used to attach a plurality of devices to each other, and various problems occur due to an increase in the number of the adhesive members.

In the semiconductor industry, integrated circuit packaging technology has been developed to satisfy requirements for small-form-factor devices and high package reliability. For instance, package techniques capable of achieving a chip-size package are actively being developed to satisfy the requirements for small-form-factor devices, and package techniques capable of promoting efficiency in a package process and improving mechanical and electrical reliability of a packaged product have attracted considerable attention in terms of high package reliability.

### SUMMARY

Some embodiments of the present disclosure provide a semiconductor package with improved structural stability and a method of fabricating the same.

Some embodiments of the present disclosure provide a simple and low-cost method of fabricating a semiconductor package and a semiconductor package fabricated by the same.

According to embodiments of the present disclosure, a semiconductor package is provided and includes: a first redistribution layer; a first semiconductor chip on the first redistribution layer; a first adhesive layer on a top surface of the first semiconductor chip; a first molding layer on the first redistribution layer, the first molding layer surrounding the first semiconductor chip and the first adhesive layer and extending between the first semiconductor chip and the first redistribution layer; a second semiconductor chip on the first adhesive layer; a second adhesive layer on a top surface of the second semiconductor chip; a second molding layer on the first molding layer, the second molding layer surrounding the second semiconductor chip and the second adhesive layer and extending between the second semiconductor chip and the first adhesive layer; and a second redistribution layer on the second molding layer, wherein the first semiconductor chip includes a first connection terminal that penetrates the first adhesive layer such that the first connection terminal is exposed at a top surface of the first adhesive layer, and wherein the second semiconductor chip includes a second connection terminal that penetrates the second molding layer such that the second connection terminal is coupled to the first connection terminal.

According to embodiments of the present disclosure, a semiconductor package is provided and includes: a first redistribution layer that includes a pad on a top surface of the first redistribution layer; a first semiconductor chip on the first redistribution layer, the first semiconductor chip including first connection terminals on a top surface of the first semiconductor chip; a first molding layer on the first redistribution layer, the first molding layer on the first semiconductor chip, and the first connection terminals is exposed at a top surface of the first molding layer; a first conductive post that penetrates the first molding layer and is coupled to the pad; a second semiconductor chip attached by a first adhesive layer to the top surface of the first molding layer; a second molding layer on the first molding layer, the second molding layer on the second semiconductor chip; a second conductive post that penetrates the second molding layer and is coupled to the first conductive post; a second redistribution layer on the second molding layer, the second redistribution layer including a wiring pattern that penetrates the second molding layer such that the wiring pattern is connected to the second semiconductor chip; and a plurality of external connection terminals on the second redistribution layer, wherein the first connection terminals are electrically connected to the second semiconductor chip.

According to embodiments of the present disclosure, a method of fabricating a semiconductor package is provided and includes: forming a first redistribution layer on a carrier substrate; forming, on the first redistribution layer, a first conductive post that vertically extends; attaching a first semiconductor chip by a first adhesive layer to a top surface of the first redistribution layer, the first semiconductor chip including first connection terminals on a top surface of the first semiconductor chip; forming, on the first redistribution layer, a first molding layer that is on the first conductive post and the first semiconductor chip; performing a grinding process to the first molding layer such that a top surface of the first conductive post and top surfaces of the first connection terminals become exposed; forming, on the first conductive post, a second conductive post that vertically extends; attaching, to the first molding layer, a second adhesive layer that is on the first connection terminals; attaching a second semiconductor chip to the second adhesive layer such that second connection terminals of the second semiconductor chip are inserted into the second adhesive layer and coupled to the first connection terminals; forming, on the first molding layer, a second molding layer that is on the second conductive post and the second semiconductor chip; performing a grinding process to the second molding layer such that a top surface of the second conductive post is exposed; and forming a second redistribution layer on the second molding layer, wherein the second semiconductor chip includes a plurality of chip pads on an inactive surface of the second semiconductor chip, and the second connection terminals are on an active surface of the second semiconductor chip.

### BRIEF DESCRIPTION OF DRAWINGS

FIG. 1 illustrates a cross-sectional view showing a semiconductor package according to some embodiments of the present disclosure.

FIG. 2 illustrates a cross-sectional view showing a semiconductor package according to some embodiments of the present disclosure.

FIG. 3 illustrates a cross-sectional view showing a semiconductor package according to some embodiments of the present disclosure.

FIG. 4 illustrates a cross-sectional view showing a semiconductor package according to some embodiments of the present disclosure.

FIG. 5 illustrates a cross-sectional view showing a semiconductor package according to some embodiments of the present disclosure.

FIG. 6 illustrates a cross-sectional view showing a semiconductor package according to some embodiments of the present disclosure . . .

FIGS. 7 to 24 illustrate cross-sectional views showing a method of fabricating a semiconductor package according to some embodiments of the present disclosure.

### DETAILED DESCRIPTION

The following will now describe a semiconductor package according to non-limiting example embodiments of the present disclosure with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

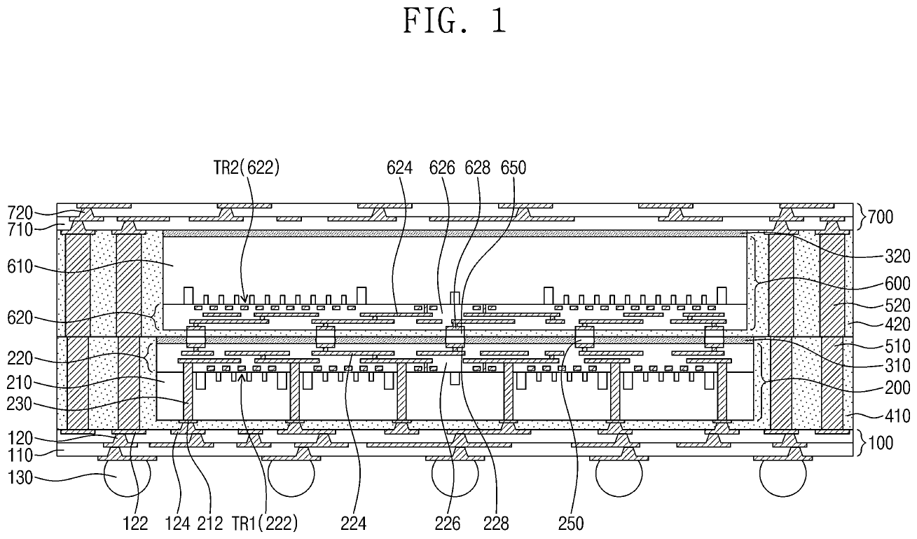

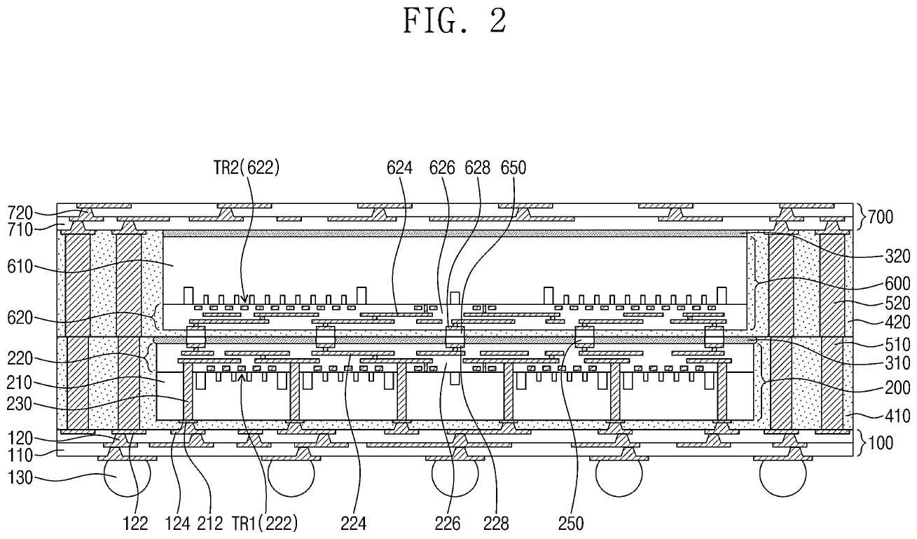

FIGS. 1 and 2 illustrate cross-sectional views showing a semiconductor package according to some embodiments of the present disclosure.

Referring to FIG. 1, a first redistribution layer 100 may be provided. The first redistribution layer 100 may include one or more first substrate wiring layers that are stacked on each other. Each of the first substrate wiring layers may include a first redistribution dielectric layer 110 and a first redistribution conductive pattern 120 in the first redistribution dielectric layer 110. When the first substrate wiring layer is provided in plural, the first redistribution conductive pattern 120 of one first substrate wiring layer may be electrically connected to the first redistribution conductive pattern 120 of an adjacent another first substrate wiring layer. In the following description, a single first substrate wiring layer will be used to explain the first redistribution dielectric layer 110 and the first redistribution conductive pattern 120.

The first redistribution dielectric layer 110 may include a photo-imageable dielectric (PID). For example, the photo-imageable dielectric may include at least one from among photosensitive polyimide (PI), polybenzoxazole (PBO), phenolic polymers, and benzocyclobutene polymers. Alternatively, the first redistribution dielectric layer 110 may include a dielectric material. For example, the first redistribution dielectric layer 110 may include silicon oxide (SiO), silicon nitride (SiN), silicon oxynitride (SiON), silicon carbonitride (SiCN), or dielectric polymers.

The first redistribution conductive pattern 120 may be provided on the first redistribution dielectric layer 110. The first redistribution conductive pattern 120 may horizontally extend on the first redistribution dielectric layer 110. The first redistribution conductive pattern 120 may be a component for redistribution in the first redistribution layer 100. The first redistribution conductive pattern 120 may include a conductive material. For example, the first redistribution conductive pattern 120 may include copper (Cu) or aluminum (Al).

The first redistribution conductive pattern 120 may have a damascene structure. For example, the first redistribution conductive pattern 120 may have a head portion and a tail portion that are integrally connected into a single unitary piece. The head and tail portions of the first redistribution conductive pattern 120 may have an inverse T-shaped cross section.

The head portion of the first redistribution conductive pattern 120 may be a pad or line part that allows a wiring line in the first redistribution layer 100 to horizontally expand. The head portion may be provided on a bottom surface of the first redistribution dielectric layer 110. For example, the head portion may protrude onto the bottom surface of the first redistribution dielectric layer 110. The first redistribution conductive pattern 120 of a lowermost one of the first substrate wiring layers may be exposed on a bottom surface of the first redistribution layer 100 or a bottom surface of a lowermost first redistribution dielectric layer 110. The first redistribution conductive pattern 120 that is exposed may be substrate pads to which external terminals 130 are coupled. Alternatively, bumps or pads may be separately provided to allow the external terminals 130 to be coupled to the bottom surface of the first redistribution layer 100, and the pads may be coupled to the first redistribution conductive pattern 120 that is exposed.

The tail portion of the first redistribution conductive pattern 120 may be a via part for vertical connection of a wiring line in the first redistribution layer 100. The tail portion may be coupled to another first substrate wiring layer that overlaps with the tail portion. For example, the tail portion of the first redistribution conductive pattern 120 may extend from a top surface of the head portion, and may penetrate the first redistribution dielectric layer 110 to be coupled to the head portion of the first redistribution conductive pattern 120 included in another first substrate wiring layer that overlaps with the tail portion of the first redistribution conductive pattern 120. No tail portion may be present in a portion 122 of the first redistribution conductive pattern 120 of an uppermost one of the first substrate wiring layers. The uppermost first redistribution conductive pattern (e.g, the portion 122) having no tail portion may be pads of the first redistribution layer 100 to which first conductive posts 510 are coupled as discussed below. Alternatively, the tail portion of another portion 124 of the uppermost first redistribution conductive pattern 120 may protrude onto a top surface of the first redistribution layer 100 or a top surface of the uppermost first redistribution dielectric layer 110. The uppermost first redistribution conductive pattern 124 having the tail portion may be coupled to a first semiconductor chip 200 which will be discussed below.

The first redistribution layer 100 may be provided with external terminals 130 on the bottom surface thereof. The external terminals 130 may be coupled to the first redistribution conductive pattern 120 of the lowermost first substrate wiring layer. The external terminals 130 may include solder balls or solder bumps, and based on a type and arrangement of the external terminals 130, a semiconductor package may be provided in the form of one from among a ball grid array (BGA) type, a fine ball-grid array (FBGA) type, and a land grid array (LGA) type.

A first semiconductor chip 200 may be disposed on the first redistribution layer 100. The first semiconductor chip 200 may be disposed vertically spaced apart from the top surface of the first redistribution layer 100. The first semiconductor chip 200 may include an integrated element therein. For example, the first semiconductor chip 200 may be a wafer-level die formed of a semiconductor, such as silicon (Si). The first semiconductor chip 200 may have a front surface and a rear surface. In the following description, the term “front surface” may be defined to indicate an active surface of an integrated element in a semiconductor chip, a surface on which wiring lines are formed, or a surface on which pads of a semiconductor chip are formed, and the term “rear surface” may be defined to indicate a surface opposite to the front surface. The rear surface of the first semiconductor chip 200 may be directed toward the first redistribution layer 100. For example, the first semiconductor chip 200 may be face-up disposed on the first redistribution layer 100.

The first semiconductor chip 200 may include a first semiconductor substrate 210, a first circuit layer 220, and vias 230.

The first semiconductor substrate 210 may be provided. The first semiconductor substrate 210 may include a semiconductor material. For example, the first semiconductor substrate 210 may be a monocrystalline silicon (Si) substrate. The first semiconductor substrate 210 may have a top surface and a bottom surface that are opposite to each other. The top surface of the first semiconductor substrate 210 may be a front surface of the first semiconductor substrate 210, and the bottom surface of the first semiconductor substrate 210 may be a rear surface of the first semiconductor substrate 210. In this description, the front surface of the first semiconductor substrate 210 may be defined to indicate a surface on which semiconductor devices are formed or mounted in the first semiconductor substrate 210 or on which wiring lines and pads are formed in the first semiconductor substrate 210, and the rear surface of the first semiconductor substrate 210 may be defined to indicate a surface opposite to the front surface. For example, the top surface of the first semiconductor substrate 210 may be an active surface.

The first semiconductor chip 200 may have the first circuit layer 220 provided on the top surface of the first semiconductor substrate 210. The first circuit layer 220 may include a first semiconductor device 222 and a first device wiring part 224.

The first semiconductor device 222 may include first transistors TR1 provided on the top surface of the first semiconductor substrate 210. For example, the first transistors TR1 may each include a source and a drain that are formed on an upper portion of the first semiconductor substrate 210, a gate electrode disposed on the top surface of the first semiconductor substrate 210, and a gate dielectric layer interposed between the first semiconductor substrate 210 and the gate electrode. The first semiconductor device 222 may include a plurality of first transistors TR1. The first semiconductor device 222 may include a logic circuit or a memory circuit. According to embodiments, the first semiconductor device 222 may include a device isolation pattern, a logic cell, or a plurality of memory cells disposed on the top surface of the first semiconductor substrate 210. Alternatively, the first semiconductor device 222 may include a passive element, such as a capacitor.

The top surface of the first semiconductor substrate 210 may be covered with a first device interlayer dielectric layer 226. The first device interlayer dielectric layer 226 may bury the first semiconductor device 222. For example, the first semiconductor device 222 may not be exposed by the first device interlayer dielectric layer 226. The first device interlayer dielectric layer 226 may include, for example, at least one from among silicon oxide (SiO), silicon nitride (SiN), and silicon oxynitride (SiON). Alternatively, the first device interlayer dielectric layer 226 may include a low-k dielectric material. The first device interlayer dielectric layer 226 may have a mono-layered structure or a multi-layered structure. When the first device interlayer dielectric layer 226 is provided in the form of the multi-layered structure, an etch stop layer may be interposed between the dielectric layers. For example, the etch stop layer may be provided on top surfaces of the dielectric layers. The etch stop layer may include, for example, one from among silicon nitride (SiN), silicon oxynitride (SiON), and silicon carbonitride (SiCN).

The first device interlayer dielectric layer 226 may be provided therein with the first device wiring part 224 connected to the first transistors TR1. The first device wiring part 224 may include wiring patterns buried in the first device interlayer dielectric layer 226. For example, the wiring patterns may include redistribution patterns for horizontal wiring and via patterns for vertical connection. The first device wiring part 224 may vertically penetrate the first device interlayer dielectric layer 226 to come into connection with one of a source electrode, a drain electrode, and a gate electrode of the first transistor TR1. Alternatively, the first device wiring part 224 may be connected to various components of the first semiconductor device 222. The first device wiring part 224 may be positioned between top and bottom surfaces of the first device interlayer dielectric layer 226. The first device wiring part 224 may include, for example, copper (Cu) or tungsten (W).

The first device interlayer dielectric layer 226 may be provided with first pads 228 on an upper portion thereof. The first pads 228 may have their top surfaces exposed at the top surface of the first device interlayer dielectric layer 226. The top surfaces of the first pads 228 may be coplanar with the top surface of the first device interlayer dielectric layer 226. The first pads 228 may be connected to the first device wiring part 224. The first pads 228 may include, for example, copper (Cu) or tungsten (W).

The first device interlayer dielectric layer 226 may be provided thereon with first connection terminals 250. The first connection terminals 250 may be disposed on the top surfaces of the first pads 228. The first connection terminals 250 may be coupled to the top surfaces of the first pads 228. For example, the first connection terminals 250 may be bonding terminals that protrude onto the top surfaces of the first pads 228. The first connection terminals 250 may include conductive bumps or solder balls. The first connection terminals 250 may include a metallic material. For example, the first connection terminals 250 may include copper (Cu).

Vias 230 may be provided to vertically penetrate the first semiconductor substrate 210 to come into connection with the first device wiring part 224. The vias 230 may be patterns for vertical wiring. The vias 230 may vertically penetrate the first device interlayer dielectric layer 226 to be coupled to a bottom surface of a portion of the first device wiring part 224. The vias 230 may vertically penetrate the first device interlayer dielectric layer 226 and the first semiconductor substrate 210 to be exposed at the bottom surface of the first semiconductor substrate 210. The vias 230 may include, for example, tungsten (W).

The first semiconductor substrate 210 may be provided with backside pads 212 on the bottom surface thereof. The backside pads 212 may be connected to the vias 230. The backside pads 212 may include, for example, copper (Cu) or tungsten (W).

The first semiconductor chip 200 may be mounted on the first redistribution layer 100. The first semiconductor chip 200 may not be in contact with the top surface of the first redistribution layer 100. The first semiconductor chip 200 may be vertically spaced apart from the top surface of the first redistribution layer 100. In this case, the another portion 124 of the first redistribution conductive pattern 120 of the first redistribution layer 100 may extend from the first redistribution layer 100 toward the first semiconductor chip 200, thereby being coupled to the backside pads 212.

A first adhesive layer 310 may be disposed on the first semiconductor chip 200. The first adhesive layer 310 may cover a top surface of the first circuit layer 220 of the first semiconductor chip 200. The first adhesive layer 310 may surround the first connection terminals 250. The first connection terminals 250 may have their top surfaces exposed at a top surface of the first adhesive layer 310. The top surfaces of the first connection terminals 250 may be coplanar with the top surface of the first adhesive layer 310. For example, the first connection terminals 250 may penetrate the first adhesive layer 310 to be coupled to the first pads 228. The first adhesive layer 310 may have a width that is the same as the width of the first semiconductor chip 200. In this case, a lateral surface of the first adhesive layer 310 may be aligned with a lateral surface of the first semiconductor chip 200. Alternatively, as shown in FIG. 2, the width of the first adhesive layer 310 may be greater than the width of the first semiconductor chip 200. The first adhesive layer 310 may protrude past the lateral surface of the first semiconductor chip 200. The first adhesive layer 310 may include a non-conductive film (NCF) or a non-conductive paste (NCP). The first adhesive layer 310 may include a dielectric polymer. For example, the first adhesive layer 310 may be formed of an epoxy-based material that contains no conductive particle. The use of the first adhesive layer 310 containing no conductive particle may achieve a fine pitch between the first connection terminals 250 without electrical short between neighboring first connection terminals 250. In addition, as the first adhesive layer 310 serves as an underfill that fills a space between the first semiconductor chip 200 and a second molding layer 420, which will be discussed below, or between the first semiconductor chip 200 and a second semiconductor chip 600, which will be discussed below, the first connection terminals 250 may increase in mechanical durability.

A first molding layer 410 may be provided on the first redistribution layer 100. On the first redistribution layer 100, the first molding layer 410 may surround the first semiconductor chip 200 and the first adhesive layer 310. The first adhesive layer 310 may be exposed at a top surface of the first molding layer 410. The top surface of the first adhesive layer 310 may be coplanar with the top surface of the first molding layer 410. The first molding layer 410 may fill a space between the first redistribution layer 100 and the first semiconductor chip 200. The another portion 124 of the first redistribution conductive pattern 120 of the first redistribution layer 100 may be penetrate the first molding layer 410 positioned between the first redistribution layer 100 and the first semiconductor chip 200, thereby being coupled to the backside pads 212. The first molding layer 410 may include a dielectric material. For example, the first molding layer 410 may include a dielectric polymer material, such as an epoxy molding compound (EMC).

First conductive posts 510 may be provided on the first redistribution layer 100. The first conductive posts 510 may serve as vertical connection terminals for connection between the first redistribution layer 100 and second conductive posts 520 which will be discussed below. The first conductive posts 510 may be horizontally spaced apart from the first semiconductor chip 200. The first conductive posts 510 may each have a pillar shape. The first conductive posts 510 may vertically penetrate the first molding layer 410. For example, the first conductive posts 510 may extend toward and be exposed at the top surface of the first molding layer 410. The first conductive posts 510 may have their top surfaces coplanar with the top surface of the first molding layer 410 and the top surface of the first adhesive layer 310. The first conductive posts 510 may extend toward a bottom surface of the first molding layer 410 to be coupled to the portion 122 (e.g., the pads) of the first redistribution conductive pattern 120. The first conductive posts 510 may include a conductive material. For example, the first conductive posts 510 may include a metallic material, such as copper (Cu) or tungsten (W).

A second semiconductor chip 600 may be disposed on the first adhesive layer 310 and the first molding layer 410. The second semiconductor chip 600 may include an integrated element therein. For example, the second semiconductor chip 600 may be a wafer-level die formed of a semiconductor, such as silicon (Si). The second semiconductor chip 600 may have a front surface and a rear surface. The front surface of the second semiconductor chip 600 may be directed towards the first redistribution layer 100. For example, the second semiconductor chip 600 may be face-down disposed on the first molding layer 410. The second semiconductor chip 600 may have a width less than the width of the first semiconductor chip 200. An entirety of the second semiconductor chip 600 may vertically overlap a portion of the first semiconductor chip 200. Another portion of the first semiconductor chip 200 may vertically overlap with the first molding layer 410 positioned on one side of the second semiconductor chip 600. However, embodiments of the present disclosure are not limited thereto, and the second semiconductor chip 600 may have a size the same as or greater than the size of the first semiconductor chip 200. The second semiconductor chip 600 may be vertically spaced apart from the first adhesive layer 310 and the first molding layer 410.

The second semiconductor chip 600 may include a second semiconductor substrate 610 and a second circuit layer 620.

The second semiconductor substrate 610 may be provided. The second semiconductor substrate 610 may include a semiconductor material. For example, the second semiconductor substrate 610 may be a monocrystalline silicon (Si) substrate. The second semiconductor substrate 610 may have a top surface and a bottom surface that are opposite to each other. The bottom surface of the second semiconductor substrate 610 may be a front surface of the second semiconductor substrate 610, and the top surface of the second semiconductor substrate 610 may be a rear surface of the second semiconductor substrate 610. In this description, the front surface of the second semiconductor substrate 610 may be defined to indicate a surface on which semiconductor devices are formed or mounted in the second semiconductor substrate 610 or on which wiring lines and pads are formed in the second semiconductor substrate 610, and the rear surface of the second semiconductor substrate 610 may be defined to indicate a surface opposite to the front surface. For example, the bottom surface of the second semiconductor substrate 610 may be an active surface.

The second semiconductor chip 600 may have the second circuit layer 620 provided on the bottom surface of the second semiconductor substrate 610. The second circuit layer 620 may include a second semiconductor device 622 and a second device wiring part 624.

The second semiconductor device 622 may include second transistors TR2 provided on the bottom surface of the second semiconductor substrate 610. For example, the second transistors TR2 may each include a source and a drain that are formed on a lower portion of the second semiconductor substrate 610, a gate electrode disposed on the bottom surface of the second semiconductor substrate 610, and a gate dielectric layer interposed between the second semiconductor substrate 610 and the gate electrode. The second semiconductor device 622 may include a plurality of second transistors TR2. The second semiconductor device 622 may include a logic circuit or a memory circuit. According to embodiments, the second semiconductor device 622 may include a device isolation pattern, a logic cell, or a plurality of memory cells disposed on the bottom surface of the second semiconductor substrate 610. Alternatively, the second semiconductor device 622 may include a passive element, such as a capacitor.

The bottom surface of the second semiconductor substrate 610 may be covered with a second device interlayer dielectric layer 626. The second device interlayer dielectric layer 626 may bury the second semiconductor device 622. For example, the second semiconductor device 622 may not be exposed by the second device interlayer dielectric layer 626. The second device interlayer dielectric layer 626 may include, for example, at least one from among silicon oxide (SiO), silicon nitride (SiN), and silicon oxynitride (SiON). Alternatively, the second device interlayer dielectric layer 626 may have a low-k dielectric material. The second device interlayer dielectric layer 626 may have a mono-layered structure or a multi-layered structure. When the second device interlayer dielectric layer 626 is provided as the multi-layered structure, an etch stop layer may be interposed between the dielectric layers.

The second device interlayer dielectric layer 626 may be provided therein with the second device wiring part 624 connected to the second transistors TR2. The second device wiring part 624 may include wiring patterns buried in the second device interlayer dielectric layer 626. For example, the wiring patterns may include redistribution patterns for horizontal wiring and via patterns for vertical connection. The second device wiring part 624 may vertically penetrate the second device interlayer dielectric layer 626 to come into connection with one from among a source electrode, a drain electrode, and a gate electrode of the second transistors TR2. Alternatively, the second device wiring part 624 may be connected to various components of the second semiconductor device 622. The second device wiring part 624 may be positioned between top and bottom surfaces of the second device interlayer dielectric layer 626. The second device wiring part 624 may include, for example, copper (Cu) or tungsten (W).

The second device interlayer dielectric layer 626 may be provided with second pads 628 on a lower portion thereof. The second pads 628 may have their bottom surfaces exposed at the bottom surface of the second device interlayer dielectric layer 626. The bottom surfaces of the second pads 628 may be coplanar with the bottom surface of the second device interlayer dielectric layer 626. The second pads 628 may be connected to the second device wiring part 624. The second pads 628 may include, for example, copper (Cu) or tungsten (W).

The second device interlayer dielectric layer 626 may be provided with second connection terminals 650 on the bottom surface thereof. The second connection terminals 650 may be disposed on the bottom surfaces of the second pads 628. The second connection terminals 650 may be coupled to the bottom surfaces of the second pads 628. For example, the second connection terminals 650 may be bonding terminals that protrude onto the bottom surfaces of the second pads 628. The second connection terminals 650 may include conductive bumps or solder balls. The second connection terminals 650 may include a metallic material. For example, the second connection terminals 650 may include copper (Cu).

The second semiconductor chip 600 may be mounted on the first semiconductor chip 200. For example, the second semiconductor chip 600 may be disposed on the first adhesive layer 310. The second circuit layer 620 of the second semiconductor chip 600 may be directed toward a top surface of the first semiconductor chip 200. The second connection terminals 650 of the second semiconductor chip 600 may be vertically aligned with the first connection terminals 250 of the first semiconductor chip 200. The first connection terminals 250 may be coupled to bottom surfaces of the second connection terminals 650. For example, the second connection terminals 650 may serve as pads of the second semiconductor chip 600 such that the first connection terminals 250 are used to mount the first semiconductor chip 200. An interface between the first connection terminals 250 and the second connection terminals 650 may be coplanar with an interface between the first adhesive layer 310 and the second molding layer 420.

A second adhesive layer 320 may be disposed on the second semiconductor chip 600. The second adhesive layer 320 may cover a top surface of the second semiconductor substrate 610 of the second semiconductor chip 600. The second adhesive layer 320 may have a width the same as a width of the second semiconductor chip 600. In this case, a lateral surface of the second adhesive layer 320 may be aligned with a lateral surface of the second semiconductor chip 600. Alternatively, the second adhesive layer 320 may protrude past the lateral surface of the second semiconductor chip 600. The second adhesive layer 320 may include a die attach film (DAF).

The second molding layer 420 may be provided on the first molding layer 410. On the first molding layer 410, the second molding layer 420 may surround the second semiconductor chip 600 and the second adhesive layer 320. The second adhesive layer 320 may be exposed at a top surface of the second molding layer 420. A top surface of the second adhesive layer 320 may be coplanar with the top surface of the second molding layer 420. The second molding layer 420 may fill a space between the first adhesive layer 310 and the second semiconductor chip 600 and a space between the first molding layer 410 and the second semiconductor chip 600. The second connection terminals 650 may penetrate a portion of the second molding layer 420 positioned between the first molding layer 410 and the second semiconductor chip 600, thereby being coupled to the first connection terminals 250. The second molding layer 420 may include a dielectric material. For example, the second molding layer 420 may include a dielectric polymer material, such as an epoxy molding compound (EMC).

Second conductive posts 520 may be provided on the first molding layer 410. The second conductive posts 520 may serve as vertical connection terminals for connecting the first conductive posts 510 to a second redistribution layer 700 which will be discussed below. The second conductive posts 520 may be horizontally spaced apart from the second semiconductor chip 600. The second conductive posts 520 may each have a pillar shape. The second conductive posts 520 may vertically penetrate the second molding layer 420. For example, the second conductive posts 520 may extend toward the top surface of the second molding layer 420. The second conductive posts 520 may extend toward a bottom surface of the second molding layer 420 to be coupled to the first conductive posts 510. A width of the second conductive posts 520 may be greater than a width of the first conductive posts 510. The second conductive posts 520 may include a conductive material. For example, the second conductive posts 520 may include a metallic material, such as copper (Cu) or tungsten (W).

A second redistribution layer 700 may be provided on the second molding layer 420. The second redistribution layer 700 may cover the top surface of the second molding layer 420 and the top surface of the second adhesive layer 320. The second redistribution layer 700 may include one or more second substrate wiring layers that are stacked on each other. Each of the second substrate wiring layers may include a second redistribution dielectric layer 710 and a second redistribution conductive pattern 720 in the second redistribution dielectric layer 710. When the second substrate wiring layer is provided in plural, the second redistribution conductive pattern 720 of one second substrate wiring layer may be electrically connected to the second redistribution conductive pattern 720 of adjacent another second substrate wiring layer. In the following description, a single second substrate wiring layer will be used to explain the second redistribution dielectric layer 710 and the second redistribution conductive pattern 720.

The second redistribution dielectric layer 710 may include a photo-imageable dielectric (PID). For example, the photo-imageable dielectric may include at least one from among photosensitive polyimide (PI), polybenzoxazole (PBO), phenolic polymers, and benzocyclobutene polymers. Alternatively, the second redistribution dielectric layer 710 may include a dielectric material. For example, the second redistribution dielectric layer 710 may include silicon oxide (SiO), silicon nitride (SiN), silicon oxynitride (SiON), silicon carbonitride (SiCN), or dielectric polymers.

The second redistribution conductive pattern 720 may be provided on the second redistribution dielectric layer 710. The second redistribution conductive pattern 720 may horizontally extend on the second redistribution dielectric layer 710. The second redistribution conductive pattern 720 may be a component for redistribution in the second redistribution layer 700. The second redistribution conductive pattern 720 may include a conductive material. For example, the second redistribution conductive pattern 720 may include copper (Cu) or aluminum (Al).

The second redistribution conductive pattern 720 may have a damascene structure. For example, the second redistribution conductive pattern 720 may have a head portion and a tail portion that are integrally connected into a single unitary piece. The head and tail portions of the second redistribution conductive pattern 720 may have an inverse T-shaped cross section.

The head portion of the second redistribution conductive pattern 720 may be a pad or line part that allows a wiring line in the second redistribution layer 700 to horizontally expand. The head portion may be provided on a bottom surface of the second redistribution dielectric layer 710. For example, the head portion may protrude onto the bottom surface of the second redistribution dielectric layer 710. The second redistribution conductive pattern 720 of a lowermost one of the second substrate wiring layers may be positioned on a bottom surface of a lowermost second redistribution dielectric layer 710 or a bottom surface of the second redistribution layer 700. A lowermost second redistribution conductive pattern 720 may be pads to which the second conductive posts 520 are coupled. For example, the second conductive posts 520 may vertically penetrate the second molding layer 420 to be coupled to a bottom surface of the lowermost second redistribution conductive pattern 720.

The tail portion of the second redistribution conductive pattern 720 may be a via part for vertical connection of a wiring line in the second redistribution layer 700. The tail portion may be coupled to another second substrate wiring layer that overlaps the tail portion. For example, the tail portion of the second redistribution conductive pattern 720 may extend from a top surface of the head portion, and may penetrate the second redistribution dielectric layer 710 to be coupled to the head portion of the second redistribution conductive pattern 720 included in another second substrate wiring layer that overlaps with the tail portion of the second redistribution conductive pattern 720. No tail portion may be present in the second redistribution conductive pattern 720 of an uppermost one of the second substrate wiring layers. The uppermost second redistribution conductive pattern 720 may be exposed at a top surface of the second redistribution layer 700, and may serve as pads for mounting another device or apparatus on a semiconductor package.

According to some embodiments of the present disclosure, the second semiconductor chip 600 may be bonded by the second adhesive layer 320 to the second redistribution layer 700, and the first semiconductor chip 200 may be bonded by the first adhesive layer 310 to the second molding layer 420. The first semiconductor chip 200 and the second semiconductor chip 600 may be rigidly adhered to other components in a semiconductor package, and the semiconductor package may improve in structural stability.

In the example embodiments that follow, a detailed description of technical features repetitive to those discussed above with reference to FIGS. 1 and 2 may be omitted, and a difference thereof will be discussed in detail. The same reference numerals may be allocated to the same components as those of the semiconductor package discussed above according to some embodiments of the present disclosure.

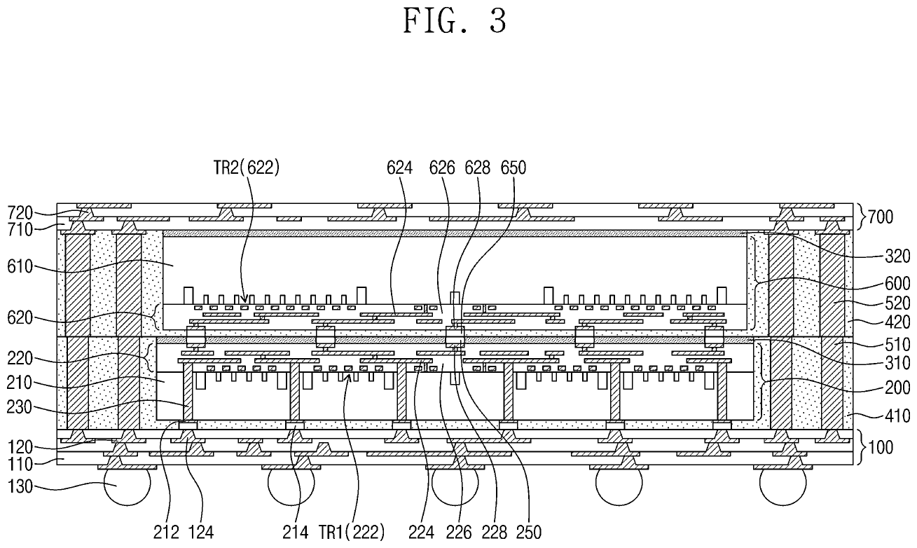

FIG. 3 illustrates a cross-sectional view showing a semiconductor package according to some embodiments of the present disclosure.

Referring to FIG. 3, third connection terminals 214 may be disposed on the bottom surface of the first semiconductor substrate 210. The third connection terminals 214 may be placed on bottom surfaces of the backside pads 212. The third connection terminals 214 may be coupled to the bottom surfaces of the backside pads 212. For example, the third connection terminals 214 may be bonding terminals that protrude onto the bottom surfaces of the backside pads 212. The third connection terminals 214 may have their bottom surfaces coplanar with a bottom surface of the first molding layer 410. The third connection terminals 214 may include conductive bumps or solder balls. The third connection terminals 214 may include a metallic material. For example, the third connection terminals 214 may include copper (Cu).

The first semiconductor chip 200 may be mounted on the first redistribution layer 100. The first semiconductor chip 200 may be mounted through the third connection terminals 214 on the first redistribution layer 100. The third connection terminals 214 may be in contact with the top surface of the first redistribution layer 100. For example, the another portion 124 of the first redistribution conductive pattern 120 may penetrate an uppermost first redistribution dielectric layer 110 to contact the third connection terminals 214. The third connection terminals 214 may be coupled to the another portion 124 of the first redistribution conductive pattern 120 of the first redistribution layer 100. The first semiconductor chip 200 may be vertically spaced apart from the first redistribution layer 100 across the third connection terminals 214. Between the first redistribution layer 100 and the first semiconductor chip 200, the first molding layer 410 may surround the third connection terminals 214 and the backside pads 212.

The first conductive posts 510 may vertically penetrate the first molding layer 410 to contact the top surface of the first redistribution layer 100. The portion 122 of the first redistribution conductive pattern 120 of the first redistribution layer 100 may penetrate the uppermost first redistribution dielectric layer 110 to be coupled to the first conductive posts 510.

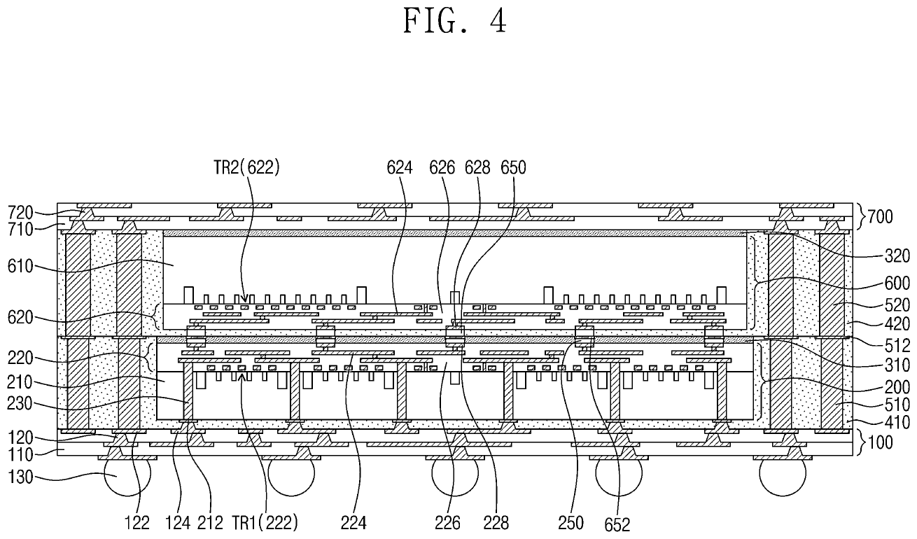

FIG. 4 illustrates a cross-sectional view showing a semiconductor package according to some embodiments of the present disclosure.

Referring to FIG. 4, first connection patterns 512 may be provided at the top surface of the first molding layer 410. The first connection patterns 512 may have their top surfaces coplanar with the top surface of the first molding layer 410. The first connection patterns 512 may be provided on the top surfaces of the first conductive posts 510. The first conductive posts 510 may vertically penetrate the first molding layer 410 to connect the first connection patterns 512 to the first redistribution conductive pattern 120 of the first redistribution layer 100. A width of the first connection patterns 512 may be greater than a width of the first conductive posts 510. The second conductive posts 520 may vertically penetrate the second molding layer 420 to connect the first connection patterns 512 to the second redistribution conductive pattern 720. The width of the first connection patterns 512 may be greater than a width of the second conductive posts 520. For example, the first connection patterns 512 may be pads for connecting the first conductive posts 510 to the second conductive posts 520.

Second connection patterns 652 may be provided at the top surface of the first adhesive layer 310. The second connection patterns 652 may have their top surfaces coplanar with the top surface of the first adhesive layer 310. The second connection patterns 652 may be provided on the first connection terminals 250. The first connection terminals 250 may be coupled to bottom surfaces of the second connection patterns 652. The first semiconductor chip 200 may be mounted through the first connection terminals 250 on the second connection patterns 652. The second connection terminals 650 may be coupled to the top surfaces of the second connection patterns 652. The second semiconductor chip 600 may be mounted through the second connection terminals 650 on the second connection patterns 652. For example, the second connection patterns 652 may be pads for connecting the first connection terminals 250 of the first semiconductor chip 200 to the second connection terminals 650 of the second semiconductor chip 600.

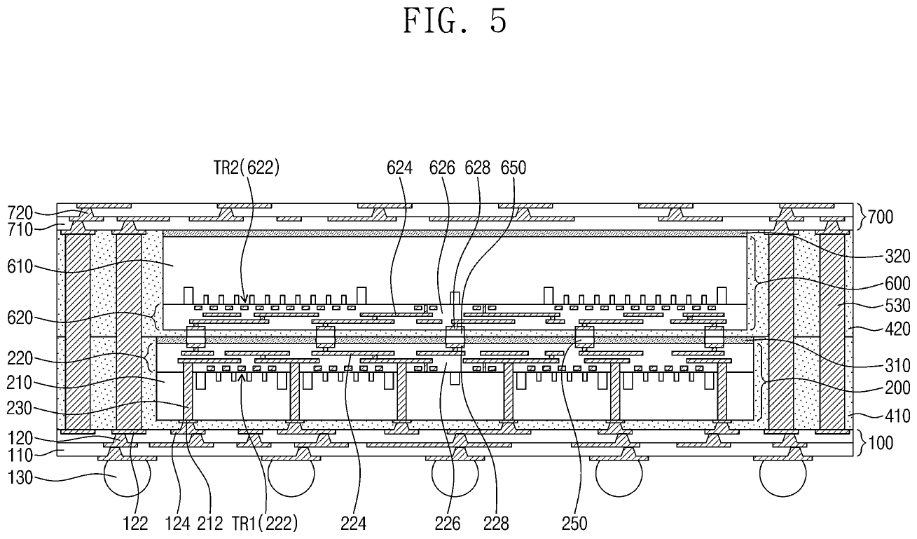

FIG. 5 illustrates a cross-sectional view showing a semiconductor package according to some embodiments of the present disclosure.

Referring to FIG. 5, a semiconductor package may include third conductive posts 530 in place of the first conductive posts 510 and the second conductive posts 520 discussed with reference to FIG. 1.

The third conductive posts 530 may be vertical connection terminals for connecting the first redistribution layer 100 to the second redistribution layer 700. The third conductive posts 530 may be horizontally spaced apart from the first semiconductor chip 200 and the second semiconductor chip 600. The third conductive posts 530 may each have a pillar shape. The third conductive posts 530 may vertically penetrate the first molding layer 410 and the second molding layer 420. For example, the third conductive posts 530 may extend toward the top surface of the second molding layer 420 to be coupled to the second redistribution conductive pattern 720 of the second redistribution layer 700. The third conductive posts 530 may extend toward the bottom surface of the first molding layer 410 to be coupled to the first redistribution conductive pattern 120 of the first redistribution layer 100. The third conductive posts 530 may include a conductive material. For example, the third conductive posts 530 may include a metallic material, such as copper (Cu) or tungsten (W).

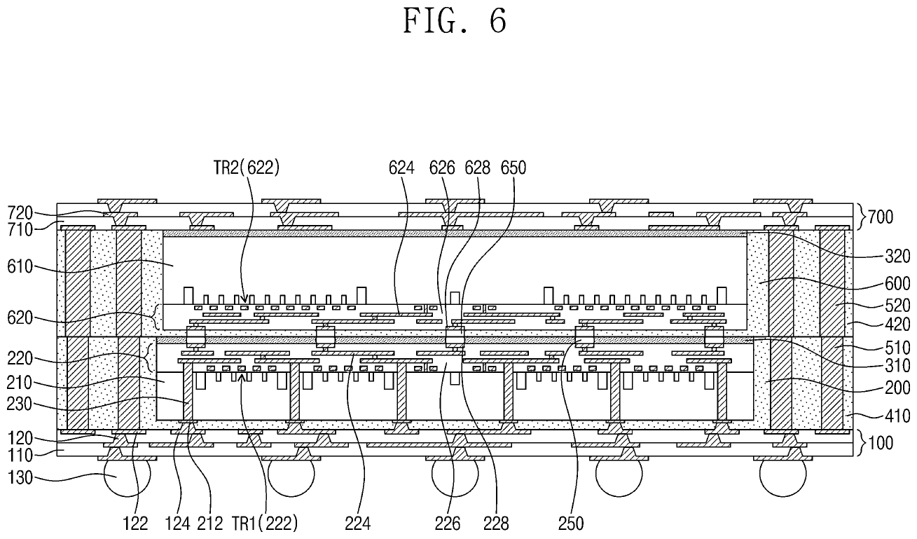

FIG. 6 illustrates a cross-sectional view showing a semiconductor package according to some embodiments of the present disclosure.

Referring to FIG. 6, the second redistribution layer 700 may be provided on the second molding layer 420. The second redistribution layer 700 may cover the top surface of the second molding layer 420 and the top surface of the second adhesive layer 320. The second redistribution layer 700 may include one or more second substrate wiring layers that are stacked on each other. Each of the second substrate wiring layers may include a second redistribution dielectric layer 710 and a second redistribution conductive pattern 720 in the second redistribution dielectric layer 710. When the second substrate wiring layer is provided in plural, the second redistribution conductive pattern 720 of one second substrate wiring layer may be electrically connected to the second redistribution conductive pattern 720 of adjacent another second substrate wiring layer. In the following description, a single second substrate wiring layer will be used to explain the second redistribution dielectric layer 710 and the second redistribution conductive pattern 720.

The second redistribution dielectric layer 710 may include a photo-imageable dielectric (PID). Alternatively, the second redistribution dielectric layer 710 may include a dielectric material.

The second redistribution conductive pattern 720 may be provided on the second redistribution dielectric layer 710. The second redistribution conductive pattern 720 may horizontally extend on the second redistribution dielectric layer 710. The second redistribution conductive pattern 720 may be a component for redistribution in the second redistribution layer 700. The second redistribution conductive pattern 720 may include a conductive material.

The second redistribution conductive pattern 720 may have a damascene structure. For example, the second redistribution conductive pattern 720 may have a head portion and a tail portion that are integrally connected into a single unitary piece. The head and tail portions of the second redistribution conductive pattern 720 may have a T-shaped cross section.

The head portion of the second redistribution conductive pattern 720 may be a pad or line part that allows a wiring line in the second redistribution layer 700 to horizontally expand. The head portion may be provided on a top surface of the second redistribution dielectric layer 710. For example, the head portion may protrude onto the top surface of the second redistribution dielectric layer 710. The second redistribution conductive pattern 720 of an uppermost one of second substrate wiring layers may be positioned on a top surface of an uppermost second redistribution dielectric layer 710 or the top surface of the second redistribution layer 700. An uppermost second redistribution conductive pattern 720 may be pads through which an external apparatus or device is coupled to a semiconductor package.

The tail portion of the second redistribution conductive pattern 720 may be a via part for vertical connection of a wiring line in the second redistribution layer 700. The tail portion may be coupled to another second substrate wiring layer that overlaps with the tail portion. For example, the tail portion of the second redistribution conductive pattern 720 may extend from a bottom surface of the head portion, and may penetrate the second redistribution dielectric layer 710 to be coupled to the head portion of the second redistribution conductive pattern 720 of adjacent another second substrate wiring layer that overlaps with the tail portion of the second redistribution conductive pattern 720. No tail portion may be present in the second redistribution conductive pattern 720 of a lowermost one of the second substrate wiring layers. The lowermost second redistribution conductive pattern 720 may be exposed at a bottom surface of the second redistribution layer 700, and may be pads to which the second conductive posts 520 are coupled. For example, the second conductive posts 520 may vertically penetrate the second molding layer 420 to be coupled to a bottom surface of the lowermost second redistribution conductive pattern 720. A portion of the lowermost second redistribution conductive pattern 720 may be a wiring pattern for horizontal wiring.

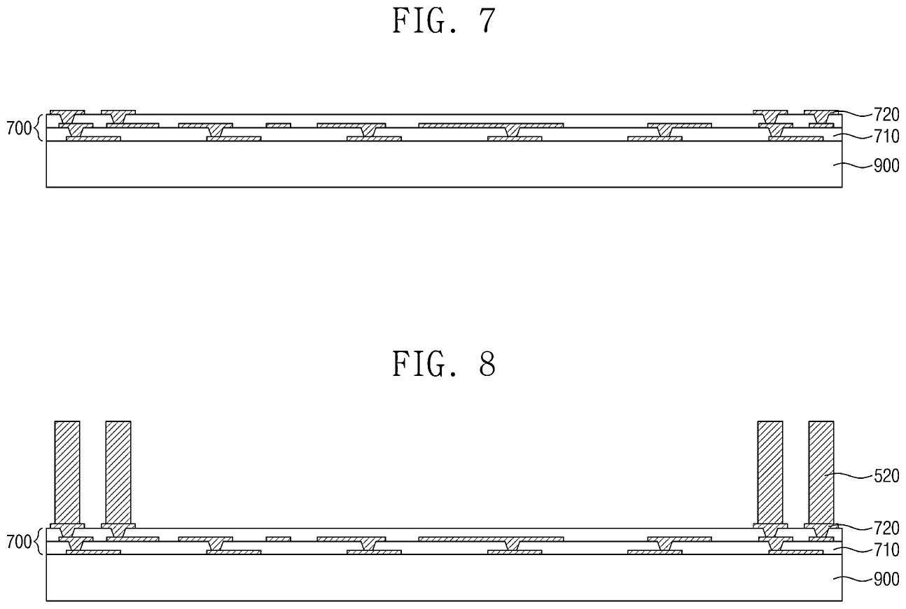

FIGS. 7 to 20 illustrate cross-sectional views showing a method of fabricating a semiconductor package according to some embodiments of the present disclosure.

Referring to FIG. 7, a first carrier substrate 900 may be provided. The first carrier substrate 900 may be a dielectric substrate including glass or polymer, or may be a conductive substrate including metal. The first carrier substrate 900 may be provided with an adhesive member on a top surface of the first carrier substrate 900. For example, the adhesive member may include a glue tape.

A second redistribution layer 700 may be formed on the first carrier substrate 900. For example, a metal layer may be formed on the first carrier substrate 900, and the metal layer may be patterned to form substrate pads. A dielectric layer may be formed on the first carrier substrate 900 to cover the substrate pads, and the dielectric layer may be patterned to form openings that expose the substrate pads, with the result that a second redistribution dielectric layer 710 may be formed. A conductive layer may be formed to cover a top surface of the second redistribution dielectric layer 710 and to fill the openings, and the conductive layer may be patterned to form a second redistribution conductive pattern 720. Therefore, a single second substrate wiring layer may be formed which includes the second redistribution dielectric layer 710 and the second redistribution conductive pattern 720. The formation of the second substrate wiring layer may be repeatedly performed to form the second redistribution layer 700.

Referring to FIG. 8, second conductive posts 520 may be formed on the second redistribution layer 700. For example, a sacrificial layer may be deposited on the second redistribution layer 700, through holes may be formed to vertically penetrate the sacrificial layer to expose the second redistribution conductive pattern 720, and then the through holes may be filled with a conductive material to form the second conductive posts 520. Afterwards, the sacrificial layer may be removed.

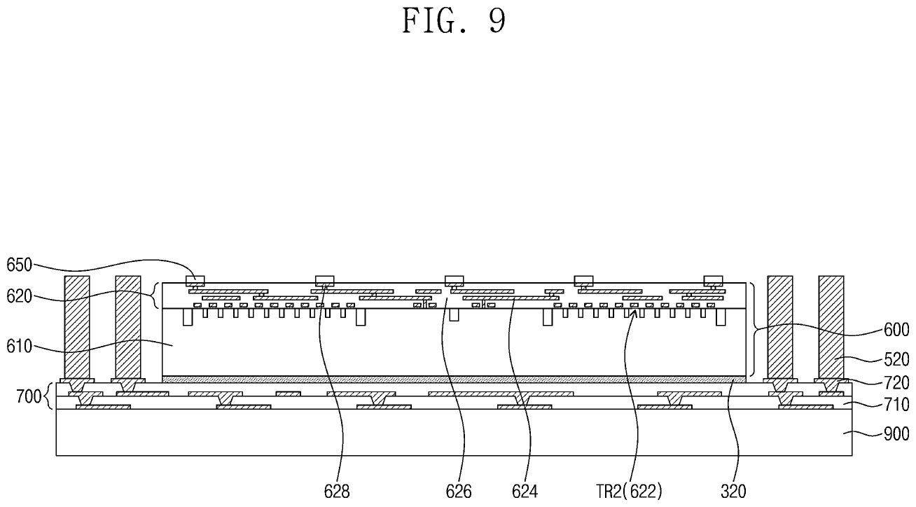

Referring to FIG. 9, a second semiconductor chip 600 may be provided. The second semiconductor chip 600 may be manufactured by an ordinary process. For example, a second semiconductor device 622 including second transistors TR2 may be formed on one surface of the second semiconductor substrate 610, a second circuit layer 620 may be formed on the one surface of the second semiconductor substrate 610 to include a second device wiring part 624 connected to the second semiconductor device 622 and a second device interlayer dielectric layer 626 covering the second semiconductor device 622, and then the second connection terminals 650 may be formed on second pads 628 of the second circuit layer 620.

Thereafter, the second semiconductor chip 600 may be attached to a top surface of the second redistribution layer 700. For example, a second adhesive layer 320 may be adhered to another surface of the second semiconductor substrate 610 of the second semiconductor chip 600, and then the second adhesive layer 320 may be used to bond the second semiconductor chip 600 to the second redistribution layer 700. The second adhesive layer 320 may include a die attach film (DAF). The second semiconductor chip 600 may be disposed between the second conductive posts 520.

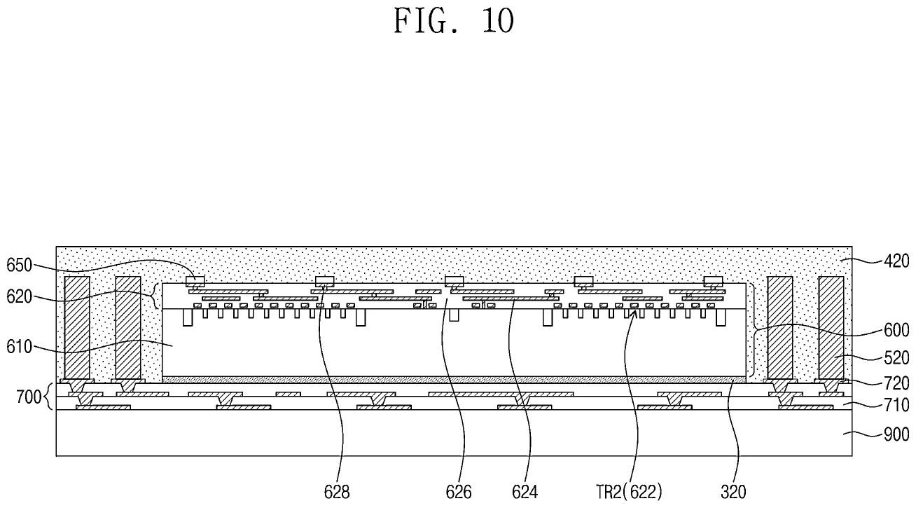

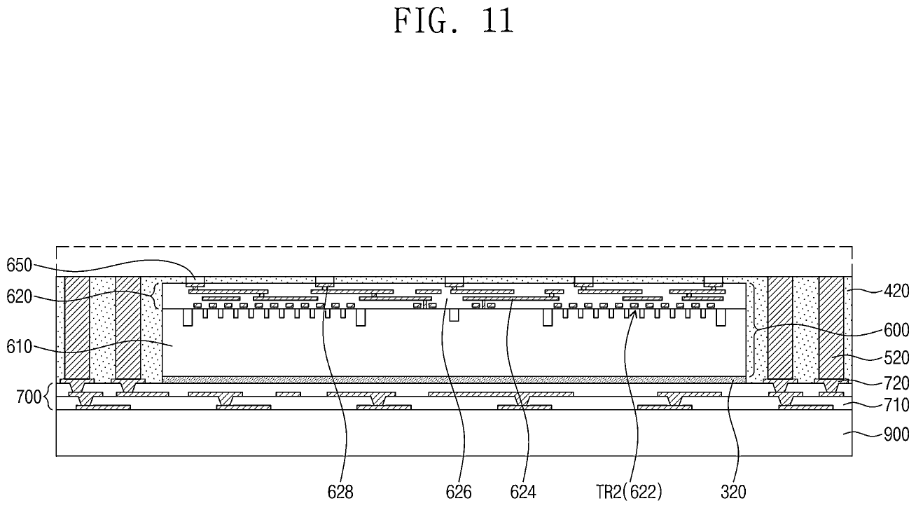

Referring to FIG. 10, a second molding layer 420 may be formed on the second redistribution layer 700. For example, a dielectric material may be coated on the second redistribution layer 700, and then the dielectric material may be cured to form the second molding layer 420. On the second redistribution layer 700, the second molding layer 420 may cover the second semiconductor chip 600 and the second conductive posts 520.

Referring to FIG. 11, a portion of the second molding layer 420 may be removed. For example, a grinding process or a chemical mechanical polishing (CMP) process may be performed on a top surface of the second molding layer 420. The grinding process or the chemical mechanical polishing process may continue until top surfaces of the second connection terminals 650 of the second semiconductor chip 600 are exposed and top surfaces of the second conductive posts 520 are exposed. The removed portions of the second molding layer 420 may be located at a level higher than a level of the top surfaces of the second connection terminals 650 and a level of the top surfaces of the second conductive posts 520. The top surface of the second molding layer 420, the top surfaces of the second connection terminals 650, and the top surfaces of the second conductive posts 520 may be substantially flat and coplanar with each other.

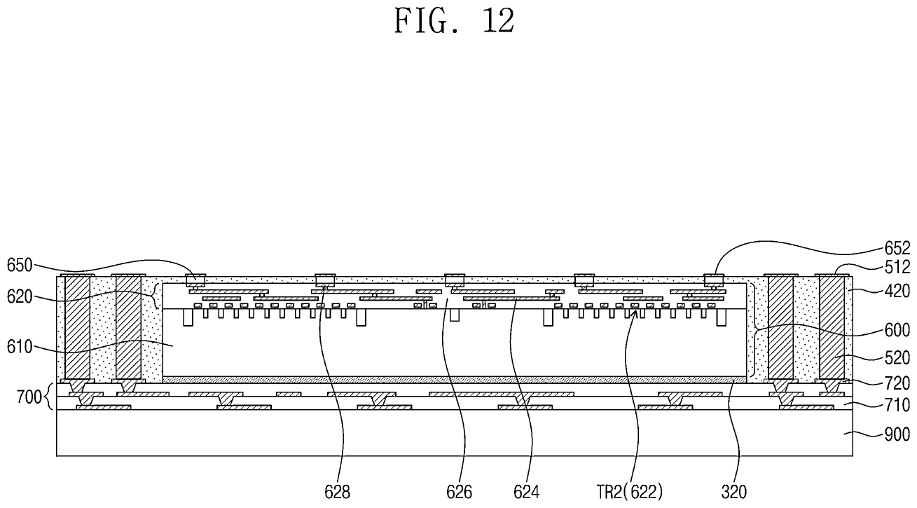

Referring to FIG. 12, first connection patterns 512 and second connection patterns 652 may be formed on the second molding layer 420. For example, a conductive layer may be formed on the top surface of the second molding layer 420, and then the conductive layer may be patterned to form the first connection patterns 512 and the second connection patterns 652. The first connection patterns 512 may be connected to the top surfaces of the second conductive posts 520. The second connection patterns 652 may be connected to the top surfaces of the second connection terminals 650. In the embodiment of FIG. 12, a semiconductor package may be fabricated which is discussed with reference to FIG. 4. The first connection patterns 512 may not be manufactured as needed. The following description will focus on the embodiment of FIG. 11.

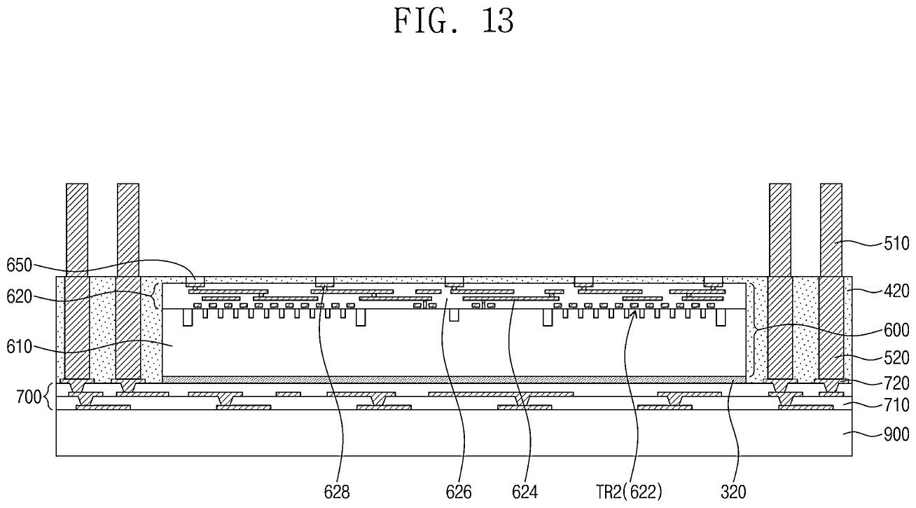

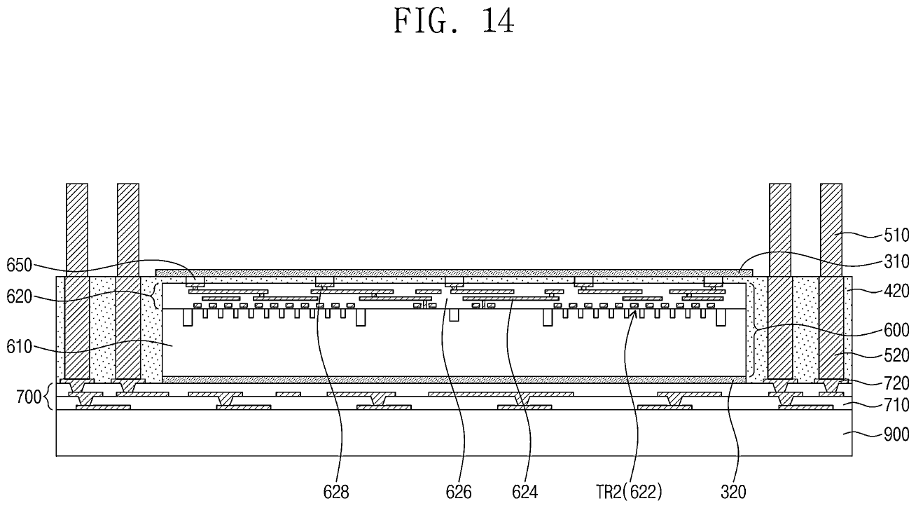

Referring to FIG. 13, on a resultant structure of FIG. 11, first conductive posts 510 may be formed on the second molding layer 420. For example, a sacrificial layer may be deposited on the second molding layer 420, through holes may be formed to vertically penetrate the sacrificial layer to expose the second conductive posts 520, and then the through holes may be filled with a conductive material to form the first conductive posts 510. A width of the through holes may be less than a width of the second conductive posts 520. Afterwards, the sacrificial layer may be removed.

Referring to FIG. 14, a first adhesive layer 310 may be attached to the second molding layer 420. The first adhesive layer 310 may cover the second connection terminals 650 exposed at the top surface of the second molding layer 420. The first adhesive layer 310 may include a non-conductive film (NCF) or a non-conductive paste (NCP). When the first adhesive layer 310 is a non-conductive adhesive, the first adhesive layer 310 may be formed by dispensing a liquid non-conductive adhesive to coat the second molding layer 420. When the first adhesive layer 310 is a non-conductive film, the first adhesive layer 310 may be formed by attaching a non-conductive film to the second molding layer 420. The first adhesive layer 310 may be disposed between the first conductive posts 510.

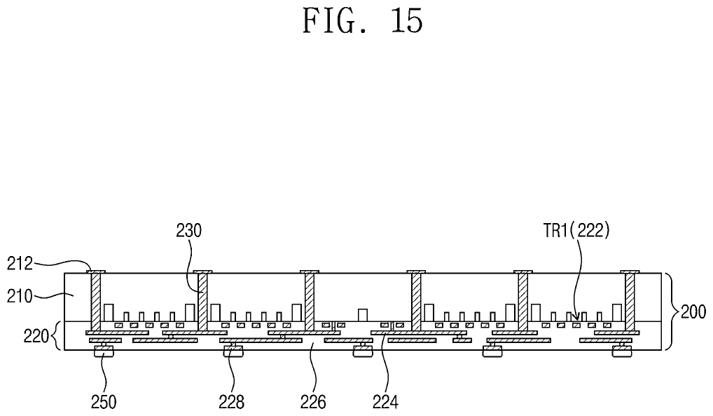

Referring to FIG. 15, a first semiconductor chip 200 may be provided. The first semiconductor chip 200 may be manufactured by an ordinary process. For example, the first semiconductor chip 200 may be manufactured by forming, on one surface of a first semiconductor substrate 210, a first semiconductor device 222 that includes first transistors TR1, forming on the one surface of the first semiconductor substrate 210 a first circuit layer 220 that includes a first device wiring part 224 connected to the first semiconductor device 222 and a first device interlayer dielectric layer 226 covering the first semiconductor device 222, forming vias 230 that penetrate the first semiconductor substrate 210 to be connected to the first device wiring part 224 and exposed at another surface of the first semiconductor substrate 210, forming on the another surface of the first semiconductor substrate 210 backside pads 212 that are connected to the vias 230, and forming first connection terminals 250 on first pads 228 of the first circuit layer 220. According to embodiments, on the another surface of the first semiconductor substrate 210, third connection terminals 214 may be formed on the backside pads 212.

According to some embodiments, the first adhesive layer 310 may be attached to the first semiconductor chip 200. In this case, the first adhesive layer 310 may be attached to the first circuit layer 220 of the first semiconductor substrate 210 of the first semiconductor chip 200. On the first circuit layer 220, the first adhesive layer 310 may surround or cover the first connection terminals 250. The following description will focus on the embodiment of FIG. 15.

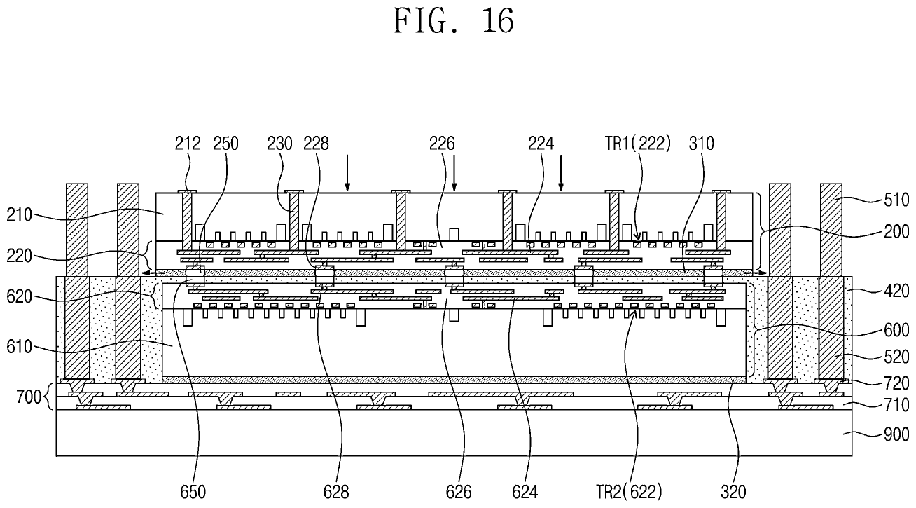

Referring to FIG. 16, a thermocompression bonding process may be employed to mount the first semiconductor chip 200 on the second connection terminals 650. The first connection terminals 250 and the second connection terminals 650 may electrically connect the first semiconductor chip 200 and the second semiconductor chip 600 to each other. For example, the first semiconductor chip 200 may be placed on the second molding layer 420 to allow the first connection terminals 250 to be aligned with the second connection terminals 650, and then a bonding tool for a bonding process may be used to cause the first semiconductor chip 200 to approach the second molding layer 420. In this step, the first connection terminals 250 may be inserted into the first adhesive layer 310, and may be in contact with the second connection terminals 650. Afterwards, the first connection terminals 250 may undergo a reflow process to bond the first connection terminals 250 to the second connection terminals 650. After the thermocompression bonding process, the first adhesive layer 310 may have the same width as a width of the first semiconductor chip 200. In this case, a semiconductor package may be fabricated which is discussed with reference to FIG. 1.

Alternatively, when the first semiconductor chip 200 is compressed in a direction toward the second molding layer 420, the first adhesive layer 310 may protrude outwardly from a lateral surface of the first semiconductor chip 200. Therefore, the first adhesive layer 310 may have a width greater than a width of the first semiconductor chip 200. In this case, a semiconductor package may be fabricated which is discussed with reference to FIG. 2. The following description will focus on the embodiment of FIG. 16.

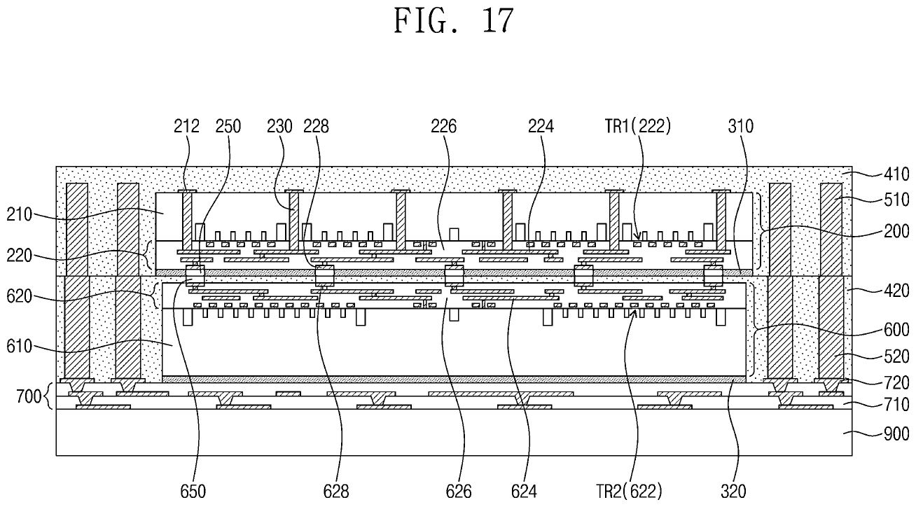

Referring to FIG. 17, a first molding layer 410 may be formed on the second molding layer 420. For example, a dielectric material may be coated on the second molding layer 420, and then the dielectric material may be cured to form the first molding layer 410. On the second molding layer 420, the first molding layer 410 may cover the first semiconductor chip 200 and the first conductive posts 510.

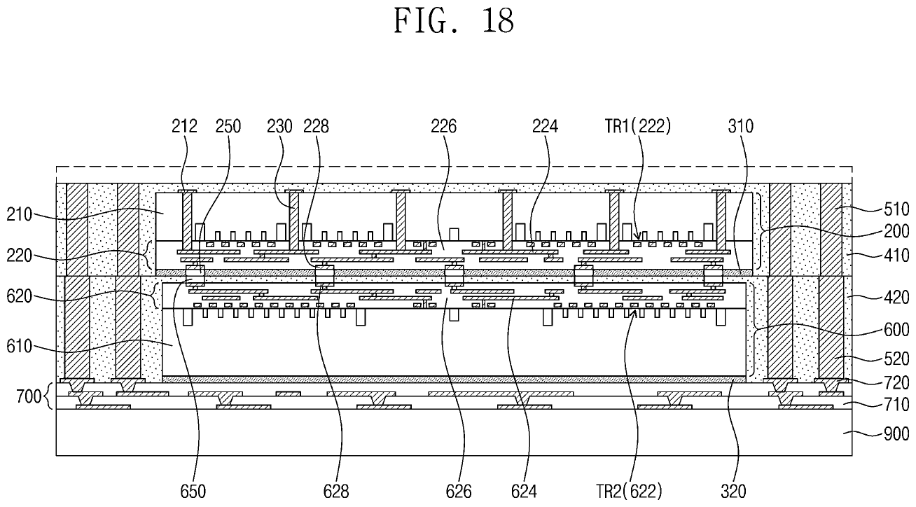

Referring to FIG. 18, a portion of the first molding layer 410 may be removed. For example, a grinding process or a chemical mechanical polishing (CMP) process may be performed on a top surface of the first molding layer 410. The grinding process or the chemical mechanical polishing process may continue until top surfaces of the first conductive posts 510 are exposed. The removed portion of the first molding layer 410 may be located at a level higher than a level of the top surfaces of the first conductive posts 510. The top surface of the first molding layer 410 and the top surfaces of the first conductive posts 510 may be substantially flat and coplanar with each other. The first semiconductor chip 200 may be covered with the first molding layer 410.

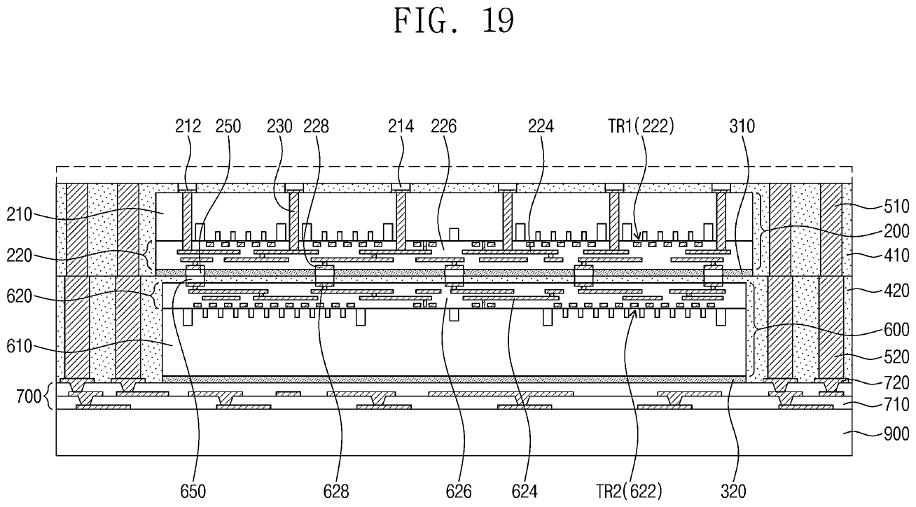

According to some embodiments, as shown in FIG. 19, when the first semiconductor chip 200 includes third connection terminals 214 provided on the backside pads 212, the grinding process or the chemical mechanical polishing process of the first molding layer 410 may continue until the top surfaces of the first conductive posts 510 and the third connection terminals 214 are exposed. Therefore, a removal action may be performed on a portion of the first molding layer 410 located at a level higher than a level of the top surfaces of the first conductive posts 510 and a level of top surfaces of the third connection terminals 214. The top surface of the first molding layer 410, the top surfaces of the third connection terminals 214, and the top surfaces of the first conductive posts 510 may be substantially flat and coplanar with each other. The following description will focus on the embodiment of FIG. 18.

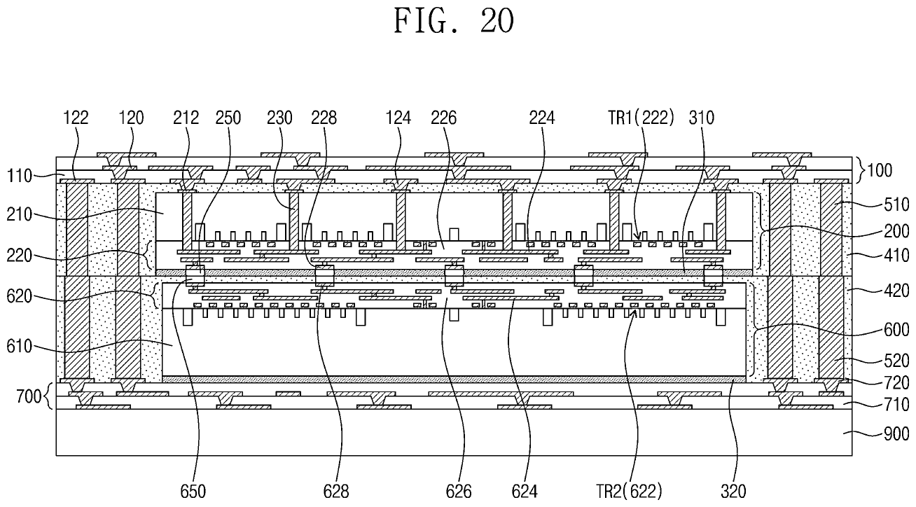

Referring to FIG. 20, a first redistribution layer 100 may be formed on the first molding layer 410. For example, the first molding layer 410 may be patterned to form openings that expose the backside pads 212 of the first semiconductor chip 200. A metal layer may be formed on the first molding layer 410 to cover the top surface of the first molding layer 410 and to fill the openings, and the metal layer may be patterned to form a first redistribution conductive pattern 120. A dielectric layer may be formed on the first molding layer 410 to cover the first redistribution conductive pattern 120, and the dielectric layer may be patterned to form openings that expose the first redistribution conductive pattern 120 to form a first redistribution dielectric layer 110. A conductive layer may be formed to cover a top surface of the first redistribution dielectric layer 110 and to fill the openings, and the conductive layer may be patterned to form a first redistribution conductive pattern 120. Therefore, a single first substrate wiring layer may be formed which includes the first redistribution dielectric layer 110 and the first redistribution conductive pattern 120. The formation of the first substrate wiring layer may be repeatedly performed to form the first redistribution layer 100.

Referring back to FIG. 1, the first carrier substrate 900 (see FIG. 20) may be removed. Then, external terminals 130 may be attached to the first redistribution layer 100.

According to some embodiments of the present disclosure, the first semiconductor chip 200 and the second semiconductor chip 600 may be attached, stacked, and mounted on one first carrier substrate 900, and in addition the first redistribution layer 100 and the second redistribution layer 700 may be formed on one first carrier substrate 900. For example, a semiconductor package fabrication process may be continuously performed on one first carrier substrate 900. Accordingly, the semiconductor package fabrication process may become simplified and decrease in manufacturing cost.

Moreover, the first semiconductor chip 200 and the second semiconductor chip 600 may be fixed by the first adhesive layer 310 and the second adhesive layer 320 in a semiconductor package, and a reflow process using solder balls or solder bumps may be used to bond the first semiconductor chip 200 and the second semiconductor chip 600 to each other. Thus, the bonding process of the first semiconductor chip 200 and the second semiconductor chip 600 may become simplified and decrease in manufacturing cost, and a semiconductor package with improved structural stability may be fabricated.

In the embodiments that follow, a detailed description of technical features repetitive to those discussed above with reference to FIGS. 7 to 20 may be omitted, and a difference thereof will be discussed in detail. The same reference numerals may be allocated to the same components as those of the semiconductor package discussed above according to some embodiments of the present disclosure.

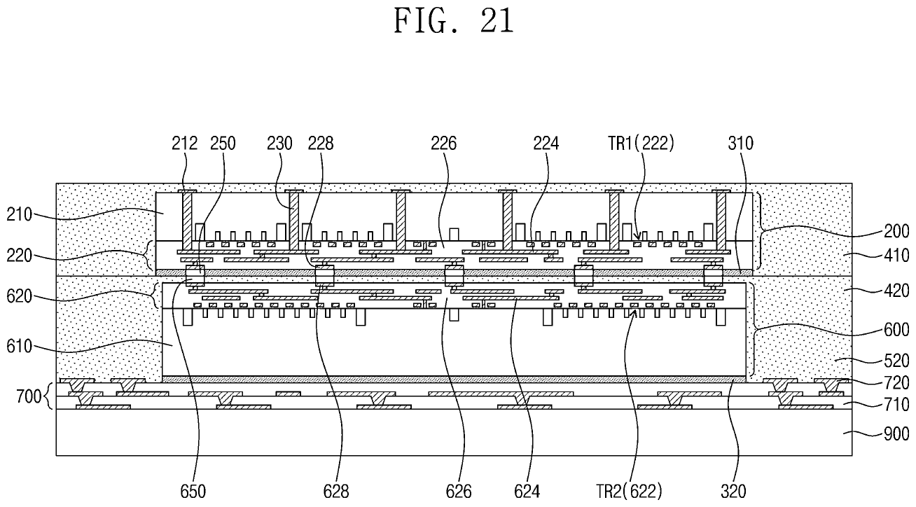

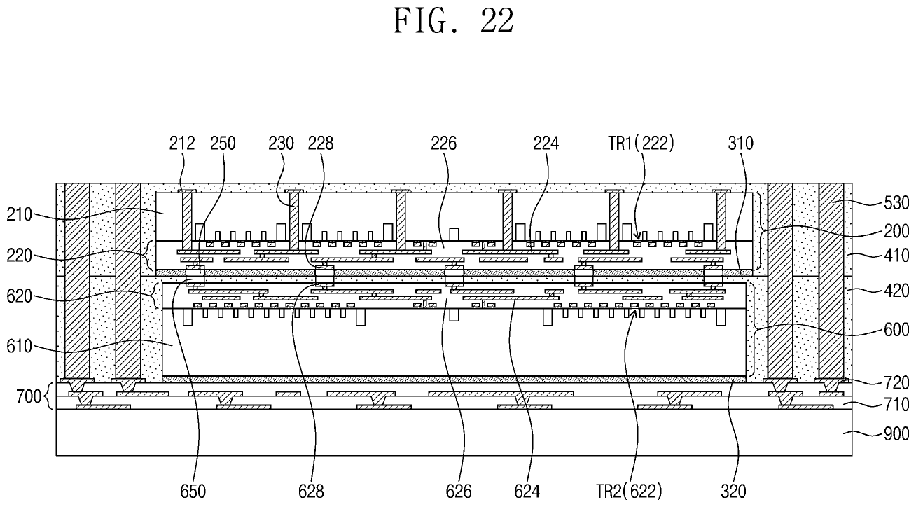

FIGS. 21 and 22 illustrate cross-sectional views showing a method of fabricating a semiconductor package according to some embodiments of the present disclosure.

Referring to FIG. 21, a second semiconductor chip 600 may be provided on a resultant structure of FIG. 7. Thereafter, the second semiconductor chip 600 may be attached to a top surface of the second redistribution layer 700. The bonding process of the second semiconductor chip 600 may be the same as or similar to the bonding process discussed with reference to FIG. 9.

A second molding layer 420 may be formed on the second redistribution layer 700. A portion of the second molding layer 420 may be removed. A grinding process or a chemical mechanical polishing (CMP) may continue until top surfaces of the second connection terminals 650 of the second semiconductor chip 600 are exposed. The formation of the second molding layer 420 and the partial removal of the second molding layer 420 may be similar to those discussed with reference to FIGS. 10 and 11.

A first adhesive layer 310 may be used to bond a first semiconductor chip 200 to the second molding layer 420. The first connection terminals 250 and the second connection terminals 650 may electrically connect the first semiconductor chip 200 and the second semiconductor chip 600 to each other. The bonding process of the first semiconductor chip 200 may be the same as or similar to that discussed with reference to FIGS. 14 to 16.

A first molding layer 410 may be formed on the second molding layer 420. For example, a dielectric material may be coated on the second molding layer 420, and then the dielectric material may be cured to form the first molding layer 410. On the second molding layer 420, the first molding layer 410 may cover the first semiconductor chip 200.

Referring to FIG. 22, third conductive posts 530 may be formed in the first molding layer 410 and the second molding layer 420. For example, through holes may be formed to vertically penetrate the first molding layer 410 and the second molding layer 420 to expose the second redistribution conductive pattern 720, and the through holes may be filled with a conductive material to form the third conductive posts 530.

Referring back to FIG. 5, a first redistribution layer 100 may be formed on the first molding layer 410. The formation of the first redistribution layer 100 may be the same as or similar to that discussed with reference to FIG. 20. The first carrier substrate 900 (see FIG. 20) may be removed. Then, external terminals 130 may be attached to the first redistribution layer 100.

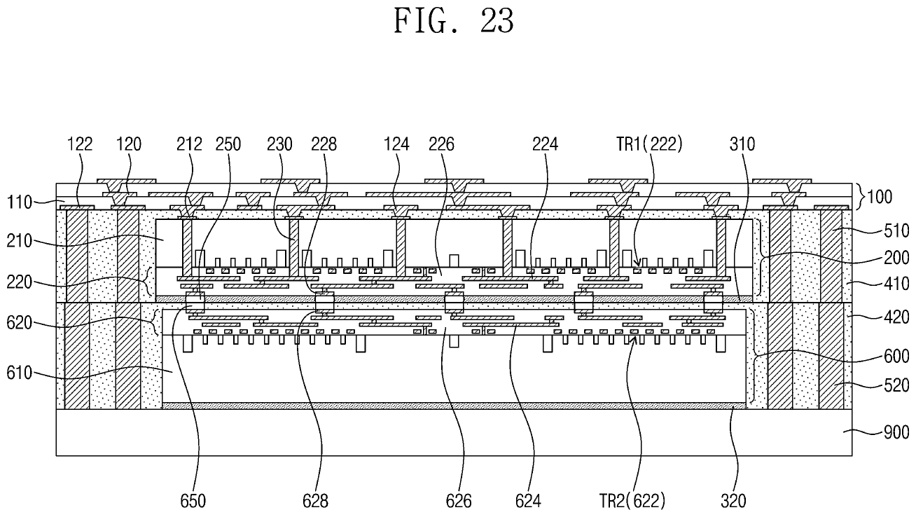

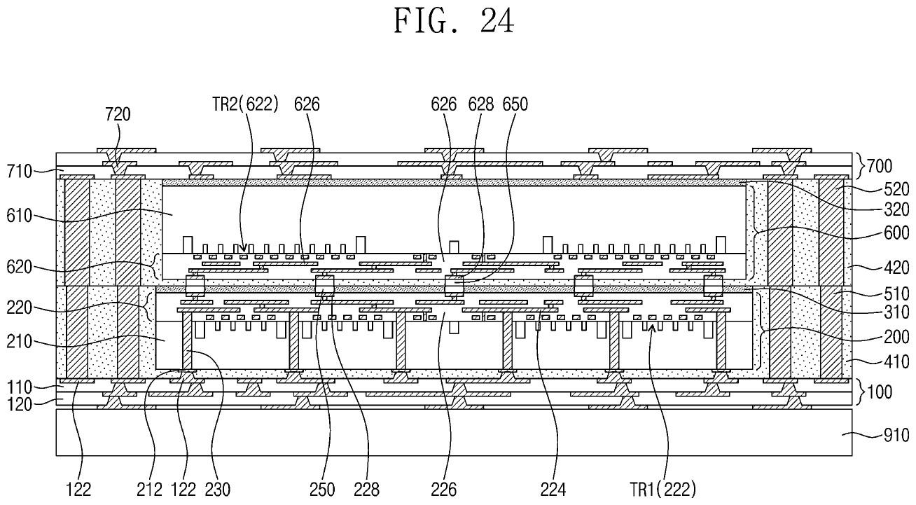

FIGS. 23 and 24 illustrate cross-sectional views showing a method of fabricating a semiconductor package according to some embodiments of the present disclosure.

Referring to FIG. 23, a first carrier substrate 900 may be provided.

Second conductive posts 520 may be formed on the first carrier substrate 900. The formation of the second conductive posts 520 may be similar to that discussed with reference to FIG. 8.

A second semiconductor chip 600 may be provided. Afterwards, the second semiconductor chip 600 may be attached to a top surface of the first carrier substrate 900. The bonding process of the second semiconductor chip 600 may be similar to the bonding process discussed with reference to FIG. 9.

A second molding layer 420 may be formed on the second redistribution layer 700. A portion of the second molding layer 420 may be removed. A grinding process or a chemical mechanical polishing process may continue until top surfaces of the second connection terminals 650 of the second semiconductor chip 600 are exposed and top surfaces of the second conductive posts 520 are exposed. The formation of the second molding layer 420 and the partial removal of the second molding layer 420 may be similar to those discussed with reference to FIGS. 10 and 11.

First conductive posts 510 may be formed on the second molding layer 420. The formation of the first conductive posts 510 may be similar to that discussed with reference to FIG. 13.

A first adhesive layer 310 may be used to bond a first semiconductor chip 200 to the second molding layer 420. The first connection terminals 250 and the second connection terminals 650 may electrically connect the first semiconductor chip 200 and the second semiconductor chip 600 to each other. The bonding process of the first semiconductor chip 200 may be the same as or similar to the bonding process discussed with reference to FIGS. 14 to 16.

A first molding layer 410 may be formed on the second molding layer 420. A portion of the first molding layer 410 may be removed. A grinding process or a chemical mechanical polishing process may continue until top surfaces of the first conductive posts 510 are exposed. The formation of the first molding layer 410 and the partial removal of the first molding layer 410 may be similar to those discussed with reference to FIGS. 17 and 18.

A first redistribution layer 100 may be formed on the first molding layer 410. The formation of the first redistribution layer 100 may be similar to that discussed with reference to FIG. 20.

Referring to FIG. 24, a second carrier substrate 910 may be attached to the first redistribution layer 100. The second carrier substrate 910 may be a dielectric substrate including glass or polymer, or may be a conductive substrate including metal. The second carrier substrate 910 may be attached through an adhesive member to the first redistribution layer 100. For example, the adhesive member may include a glue tape.

A resultant structure may be turned over to cause the first carrier substrate 900 to reside above the second carrier substrate 910.

After that, the first carrier substrate 900 may be removed. This step may expose a top surface of the second adhesive layer 320, a top surface of the second molding layer 420, and top surfaces of the second conductive posts 520.

A second redistribution layer 700 may be formed on the second molding layer 420. For example, a metal layer may be formed on the second molding layer 420 to cover the top surface of the second molding layer 420, and the metal layer may be patterned to form a second redistribution conductive pattern 720. A dielectric layer may be formed on the second molding layer 420 to cover the second redistribution conductive pattern 720, and the dielectric layer may be patterned to form openings that expose the second redistribution conductive pattern 720 to form a second redistribution dielectric layer 710. A conductive layer may be formed to cover a top surface of the second redistribution dielectric layer 710 and to fill the openings, and the conductive layer may be patterned to form a second redistribution conductive pattern 720. Therefore, a single second substrate wiring layer may be formed which includes the second redistribution dielectric layer 710 and the second redistribution conductive pattern 720. The formation of the second substrate wiring layer may be repeatedly performed to form the second redistribution layer 700.

Referring back to FIG. 6, the second carrier substrate 910 (see FIG. 24) may be removed. Then, external terminals 130 may be attached to the first redistribution layer 100.

In a semiconductor package according to some embodiments of the present disclosure, a second semiconductor chip may be attached through a second adhesive layer to a second redistribution layer, and a first semiconductor chip may be attached through a first adhesive layer to a second molding layer. For example, semiconductor chips may be rigidly adhered to other components in the semiconductor package, and the semiconductor package may improve in structural stability.

In a method of fabricating a semiconductor package according to some embodiments of the present disclosure, semiconductor chips may be attached, stacked, and mounted on one carrier substrate, and redistribution layers may be formed on one carrier substrate. For example, a semiconductor package fabrication process may be continuously performed on one carrier substrate. Accordingly, the semiconductor package fabrication may become simplified and decrease in manufacturing cost.

Moreover, the semiconductor chips may be fixed through adhesive layers in the semiconductor package, and a reflow process may be used to bond the semiconductor chips to each other. Thus, the bonding process of the semiconductor chips may become simplified and decrease in manufacturing cost, and the semiconductor package may improve in structural stability.

Although non-limiting example embodiments of the present disclosure have been described in connection with the accompanying drawings, it will be understood by one of ordinary skill in the art that variations in form and detail may be made therein without departing from the spirit and scope of the present disclosure. The example embodiments described above should thus be considered illustrative and not restrictive.

What is claimed is:

1. A semiconductor package, comprising:
a first redistribution layer;
a first semiconductor chip on the first redistribution layer;
a first adhesive layer on a top surface of the first semiconductor chip;
a first molding layer on the first redistribution layer, the first molding layer surrounding the first semiconductor chip and the first adhesive layer and extending between the first semiconductor chip and the first redistribution layer;
a second semiconductor chip on the first adhesive layer;
a second adhesive layer on a top surface of the second semiconductor chip;
a second molding layer on the first molding layer, the second molding layer surrounding the second semiconductor chip and the second adhesive layer and extending between the second semiconductor chip and the first adhesive layer; and
a second redistribution layer on the second molding layer,
wherein the first semiconductor chip comprises a first connection terminal that penetrates the first adhesive layer such that the first connection terminal is exposed at a top surface of the first adhesive layer, and
wherein the second semiconductor chip comprises a second connection terminal that penetrates the second molding layer such that the second connection terminal is coupled to the first connection terminal.

2. The semiconductor package of claim 1, wherein
the first semiconductor chip is attached by the first adhesive layer to a bottom surface of the second molding layer, and
the second semiconductor chip is attached by the second adhesive layer to a bottom surface of the second redistribution layer.

3. The semiconductor package of claim 1, wherein the first semiconductor chip further comprises:
a chip pad on a bottom surface of the first semiconductor chip; and
a chip via that vertically penetrates the first semiconductor chip such that the chip via is connected to the chip pad,
wherein the chip pad is electrically connected to the first redistribution layer.

4. The semiconductor package of claim 3, wherein the first redistribution layer comprises:
a dielectric pattern; and
a wiring pattern in the dielectric pattern,
wherein a portion of the wiring pattern penetrates the first molding layer such that the portion of the wiring pattern is connected to the chip pad.

5. The semiconductor package of claim 3, wherein the first redistribution layer comprises:
a dielectric pattern; and
a wiring pattern in the dielectric pattern,
wherein the first semiconductor chip further comprises a third connection terminal on the chip pad, the third connection terminal penetrating the first molding layer such that the third connection terminal is exposed at a bottom surface of the first molding layer, and
wherein a portion of the wiring pattern penetrates the dielectric pattern such that the portion of the wiring pattern is connected to the third connection terminal.

6. The semiconductor package of claim 1, further comprising:
a first conductive post that vertically penetrates the first molding layer such that the first conductive post is connected to the first redistribution layer; and
a second conductive post that vertically penetrates the second molding layer such that the second conductive post is connected to the first conductive post and the second redistribution layer, or
a third conductive post that vertically penetrates the first molding layer and the second molding layer such that the third conductive post connects the first redistribution layer and the second redistribution layer to each other.

7. The semiconductor package of claim 1, wherein
the first semiconductor chip is vertically spaced apart from the first redistribution layer across the first molding layer, and
the second semiconductor chip is vertically spaced apart from the first molding layer and the first adhesive layer across the second molding layer.

8. The semiconductor package of claim 1, wherein
the top surface of the first adhesive layer is coplanar with a top surface of the first molding layer, and
a top surface of the second adhesive layer is coplanar with a top surface of the second molding layer.

9. The semiconductor package of claim 1, further comprising a plurality of external connection terminals on a bottom surface of the first redistribution layer.

10. The semiconductor package of claim 1, wherein an interface between the first connection terminal and the second connection terminal is coplanar with an interface between the first adhesive layer and the second molding layer.

11. The semiconductor package of claim 1, wherein a width of the second adhesive layer is the same as or greater than a width of the first semiconductor chip.

12. A semiconductor package, comprising:
a first redistribution layer that comprises a pad on a top surface of the first redistribution layer;
a first semiconductor chip on the first redistribution layer, the first semiconductor chip comprising first connection terminals on a top surface of the first semiconductor chip;
a first molding layer on the first redistribution layer, the first molding layer on the first semiconductor chip, and the first connection terminals is exposed at a top surface of the first molding layer;
a first conductive post that penetrates the first molding layer and is coupled to the pad;
a second semiconductor chip attached by a first adhesive layer to the top surface of the first molding layer;
a second molding layer on the first molding layer, the second molding layer on the second semiconductor chip;
a second conductive post that penetrates the second molding layer and is coupled to the first conductive post;
a second redistribution layer on the second molding layer, the second redistribution layer comprising a wiring pattern that penetrates the second molding layer such that the wiring pattern is connected to the second semiconductor chip; and
a plurality of external connection terminals on the second redistribution layer,
wherein the first connection terminals are electrically connected to the second semiconductor chip.

13. The semiconductor package of claim 12, wherein the first semiconductor chip is attached by a second adhesive layer to the top surface of the first redistribution layer.

14. The semiconductor package of claim 12, wherein the second semiconductor chip comprises a plurality of second connection terminals on a bottom surface of the second semiconductor chip, and
wherein the second connection terminals penetrate the first adhesive layer such that the second connection terminals are connected to the first connection terminals.

15. The semiconductor package of claim 12, wherein the second semiconductor chip comprises:
a chip pad on a top surface of the second semiconductor chip; and
a chip via that vertically penetrates the second semiconductor chip such that the chip via is connected to the chip pad,
wherein the wiring pattern is coupled to the chip pad.

16. The semiconductor package of claim 12, wherein
the first molding layer is on the top surface of the first semiconductor chip, and
the first molding layer vertically separates the top surface of the first semiconductor chip from the first adhesive layer or the second molding layer.

17. The semiconductor package of claim 12, wherein a width of the first adhesive layer is the same as or greater than a width of the second semiconductor chip.

18. The semiconductor package of claim 12, wherein a width of the second conductive post is less than a width of the first conductive post.

19. The semiconductor package of claim 12, wherein an active surface of the first semiconductor chip faces an active surface of the second semiconductor chip.

20. A method of fabricating a semiconductor package, the method comprising:
forming a first redistribution layer on a carrier substrate;
forming, on the first redistribution layer, a first conductive post that vertically extends;
attaching a first semiconductor chip by a first adhesive layer to a top surface of the first redistribution layer, the first semiconductor chip including first connection terminals on a top surface of the first semiconductor chip;
forming, on the first redistribution layer, a first molding layer that is on the first conductive post and the first semiconductor chip;
performing a grinding process to the first molding layer such that a top surface of the first conductive post and top surfaces of the first connection terminals become exposed;
forming, on the first conductive post, a second conductive post that vertically extends;
attaching, to the first molding layer, a second adhesive layer that is on the first connection terminals;
attaching a second semiconductor chip to the second adhesive layer such that second connection terminals of the second semiconductor chip are inserted into the second adhesive layer and coupled to the first connection terminals;
forming, on the first molding layer, a second molding layer that is on the second conductive post and the second semiconductor chip;
performing a grinding process to the second molding layer such that a top surface of the second conductive post is exposed; and
forming a second redistribution layer on the second molding layer,
wherein the second semiconductor chip includes a plurality of chip pads on an inactive surface of the second semiconductor chip, and the second connection terminals are on an active surface of the second semiconductor chip.
